(19) United States
(12) Patent Application Publication
(10) Pub. No.: US 2022/0037269 A1
(43) Pub. Date: Feb. 3, 2022

(54) Semiconductor device for power electronics applications

(71) Applicant: X-FAB Global Services GmbH, Erfurt (DE)

(72) Inventors: Ralf LERNER, Erfurt (DE); Nis Hauke HANSEN, Erfurt (DE)

(21) Appl. No.: 17/371,622

(22) Filed: Jul. 9, 2021

(30) Foreign Application Priority Data
Jul. 10, 2020 (DE) 10 2020 118 340.2
Oct. 20, 2020 (DE) 10 2020 127 640.0

(51) Int. Cl. H01L 23/64; H03K 17/041

(52) U.S. Cl. CPC H01L 23/642; H03K 17/04106

(57) ABSTRACT

The present invention suggests a semiconductor device for integration into a power module. The semiconductor device comprises (a) a semiconductor layer (10), a first side of the semiconductor layer (10) having a plurality of depressions (11); (b) an insulating layer (12; 12a, 12b), the insulating layer being deposited on the first side of the semiconductor layer (10) and engaging in the depressions (11); (c) a first electrically conductive layer (14; 14a, 14b) for contacting the semiconductor device (1, 2), the first electrically conductive layer (14; 14a, 14b) being deposited on the insulating layer (12a, 12b); and (d) a second electrically conductive layer (16) for contacting the semiconductor device (1, 2), the second electrically conductive layer (16) being deposited on a second side of the semiconductor layer (10) opposite to the first side. The first electrically conductive layer (14; 14a, 14b) has a plurality of recesses (20, 20) and a plurality of subregions (24), and each subregion (24) is enclosed by at least one recess (20), leaving at least one region (22, 22) having a narrowed cross-section.

### FIELD OF INVENTION

The present invention relates to a semiconductor device for application in power electronics and for integration in a power module. Power modules consist of (semiconductor) devices or power semiconductors which, in power electronics, are designed and configured for switching high electronic currents (1 A to several 1,000 A) and/or high voltages (higher than at least 24 V, but typically above 100 V). Examples of power semiconductors are power diodes, thyristors or power transistors, such as power MOSFETs, GTOs and IGBT devices. In electric circuits, so-called snubbers (snubber elements, Boucherot elements) are used for damping unwanted oscillations within an electric circuit or for dissipating current or voltage peaks and thus avoid them. Unwanted oscillations or voltage peaks occur in particular during switching off of inductive loads, when the current flow is abruptly interrupted.

These above-mentioned devices are also realized as four-layer structures, the snubbers concerning primarily the turning-off or switching-off, less the switching-on of these devices.

Snubbers are used in electronics, for example as an RC snubber element. An RC snubber element is a series connection of a capacitor with a resistor. Functionally, they are passive relief elements used in the field of circuit technology, which are intended to keep loads away from the (de)switching power semiconductors. Anyone who knows inductive loads and works with them can easily understand how important these passive circuits are, since there is an inductive element in virtually every power circuit, even though it may be parasitic.

The prior art discloses various semiconductor devices that implement an integrated RC snubber element, i.e. capacitor and resistor integrated in one device.

### BACKGROUND

U.S. Pat. No. 7,738,226 B2 or U.S. Pat. No. 8,563,388 B2 each disclose an integrated RC snubber device. The device comprises a silicon substrate (resistive component) having a plurality of trenches on one side (front side). The side of the silicon substrate with the trenches is coated with an insulating layer (capacitive component). An electrically conductive material is deposited on the side of the silicon substrate with the trenches for contacting and also fills the coated trenches. Also a side of the silicon substrate (rear side) opposite to the side with the trenches has deposited thereon electrically conductive material for contacting the device.

US 2019/007041 A1 or U.S. Pat. No. 8,705,257 B2 show the use of the above-described device in a power module.

U.S. Pat. Nos. 8,330,247 B2, 9,455,151 B2 or 9,917,146 B2 show specific design forms of the trenches and the insulating layers and additional trenches on the rear side of the substrate.

### SUMMARY OF INVENTION

An object of the present invention is to be seen in the provision of a semiconductor device guaranteeing a higher safety level when used with power semiconductors and having at the same time a longer service life.

This object is achieved by a semiconductor device according to claim 1, a semiconductor device according to claim 8 and a semiconductor device according to claim 12. Also a method according to claim 24 allows the object to be achieved.

According to a first invention, a semiconductor device for integration in a power module comprises a semiconductor layer, an insulating layer, a first electrically conductive layer for contacting the semiconductor device, and a second electrically conductive layer for contacting the semiconductor device. The semiconductor layer comprises a first side having a plurality of depressions. The first side of the semiconductor layer has deposited thereon the insulating layer and engages in the depressions. The first electrically conductive layer is deposited on the insulating layer and the second electrically conductive layer is deposited on a second side of the semiconductor layer, which is located opposite to the first side.

The first electrically conductive layer has a plurality of recesses, which each enclose a subregion of the first electrically conductive layer, leaving a region having a narrowed cross-section.

The first electrically conductive layer may also have a plurality of recesses and a plurality of subregions, and each subregion is enclosed by at least one recess, leaving at least one region having a narrowed cross-section.

The semiconductor device may be a microelectronic device. Accordingly, the individual (thin) layers of the semiconductor device may each have layer thicknesses in the nanometer to micrometer range.

The semiconductor layer may comprise silicon, preferably it may consist of silicon.

The depressions (pits) in the semiconductor layer can be produced e.g. by means of deep reactive ion etching (DRIE).

Preferably, the semiconductor layer may comprise several hundred depressions that are identical to each other and that may be arranged in a grid on or in the semiconductor layer.

The insulating layer may comprise a dielectric, preferably it may be a dielectric. For example, the insulating layer may comprise ceramics, plastics or plastic mixtures as well as electrolytic (double) layers and oxide layers, respectively.

The first and the second electrically conductive layer used for contacting may each comprise a metal, preferably be made of metal, further preferably be made of aluminum.

Via the first and the second electrically conductive layer, the semiconductor device can be contacted and connected to other (semiconductor) devices.

The number of recesses in the first electrically conductive layer may correspond to the number of depressions. Each recess may be associated with a depression. The recesses may be identical to one another and/or arranged in a grid on or in the first electrically conductive layer.

The regions having a narrowed cross-section may each be defined by a recess, preferably the recesses define a respective width of the cross-section. The height (z-direction) of the cross-sections may be determined by a layer thickness of a (planar) portion of the first electrically conductive layer. A width and a length of a cross-section with a narrowed region, representative of all regions having a narrowed cross-section, may be determined by the respective recess. Narrowed in this context may mean that the length (x-direction) of the region having a narrowed cross-section is many times smaller than a length of the first electrically conductive layer, and that the width (y-direction) of the region having a narrowed cross-section is many times smaller than a width of the first electrically conductive layer.

Narrowed is e.g. also the web width in comparison with the bent length of the recess. It is longer than the remaining (residual) web, as a more concrete paraphrase of the term “narrowed” (or constricted).

The number of recesses in the first electrically conductive layer may, however, also be smaller than the number of depressions. For example, one recess may be associated with two depressions.

Accordingly, one or a plurality of subregions in the first electrically conductive layer may each be enclosed by a plurality of recesses, leaving a plurality of regions having a narrowed cross-section. A respective plurality of recesses is here associated with a subregion, as are the plurality of regions having a narrowed cross-section that are also associated with a respective subregion.

For example, two recesses may enclose a subregion of the first electrically conductive layer only to the extent that two regions having a narrowed cross-section remain in the first electrically conductive layer.

The regions having a narrowed cross-section in the first electrically conductive layer may each have a height between 100.0 nm and 1.0 μm and a width between 50.0 nm and 5.0 μm. Preferably, the height may be between 400.0 nm and 800.0 nm and the width may be between 1.0 μm and 2.0 μm.

The regions having a narrowed cross-section may each have the same height and the same width.

Through the width and the height (and a length) of a region having a narrowed cross-section it can be determined and/or adjusted how much current can be conducted through the region without the latter being damaged during trouble-free operation of the semiconductor device.

Each depression in the first electrically conductive layer can be regarded as a (pit) capacitor. Accordingly, the semiconductor device can comprise a plurality of (pit) capacitors connected in parallel with each other. The regions having a narrowed cross-section can be regarded as defined connection conductive paths. If a certain (limit) current density is exceeded, for example if a subregion of the insulating layer fails, a single region having a narrowed cross-section or singulated regions having a narrowed cross-section may melt through and thus electrically isolate one pit capacitor or singulated pit capacitors, so that the semiconductor device integrated in a power module can continue to operate and other electronic components of the power module will not be damaged.

All the depressions in the first electrically conductive layer may be produced in one process step, e.g. in an etch process step.

A respective subregion in the first electrically conductive layer may at least partially cover, preferably completely cover, a respective opening of a depression, and more preferably extend radially beyond an edge of the respective opening of the depression.

In addition, a respective subregion in the first electrically conductive layer may at least partially cover, preferably completely cover, a plurality of openings of associated depressions, and more preferably extend radially beyond edges of the respective openings.

The recesses may have a circular (annular), partially circular, rectangular or polygonal basic shape. Correspondingly, the (exempted) subregions in the first electrically conductive layer may have a circular, rectangular or polygonal basic shape.

If a plurality of recesses are associated with a subregion, the total view of the recesses per subregion will have to be considered.

A further semiconductor device for integration in a power module according to the present invention comprises a semiconductor layer, an insulating layer, a first electrically conductive semiconductor layer for contacting the semiconductor device, and a second electrically conductive layer for contacting the semiconductor device. The semiconductor layer comprises a first side provided with a plurality of depressions as pits. The insulating layer is deposited on the first side of the semiconductor layer and extends into the pits. The first electrically conductive layer for contacting the semiconductor device is deposited on the insulating layer and extends into, but does not fill, the pits. The second electrically conductive layer is deposited on a second side of the semiconductor layer, which is located opposite to the first side.

The insulating layer has thickenings in the opening areas of the pits, so as to define respective conductive regions having a narrowed cross-section in the first electrically conductive layer.

The depression and/or the plurality of depressions provided as pits in the first side of the semiconductor layer may be produced by means of etching processes, e.g. by means of deep reactive ion etching (DRIE).

Preferably, a plurality of pits may be provided in the semiconductor layer. These pits may be produced in a single etching process step.

The pits may be arranged in the semiconductor layer in a grid.

Each thickening in the insulating layer may extend radially inwards in the shape of a bulge, viewed from a respective side wall of the depression. In this context, close to the opening area (close to the edge) can mean that a respective thickening is arranged in the upper third of a depression.

Preferably, the respective thickenings are arranged in the opening areas of the pits in such a way that, in a process step in which the first electrically conductive layer is deposited, cavities will be formed in the pits below the thickenings. This respective cavity may be regarded as an inclusion in the first electrically conductive layer and may be filled with a gas, by way of example.

The regions having a narrowed cross-section in the first electrically conductive layer may each have a first diameter between 100.0 nm and 2.0 μm. Preferably, the range is between 300.0 nm and 700.0 nm. The first diameter may here be the smallest diameter that the respective regions with a narrowed cross-section have.

Each pit may, sectionwise, have a second diameter. A ratio of the first diameter to the second diameter may be between 1:2 and 1:20. Preferably, the range is between 1:5 and 1:15. The first diameter is thus up to 20 times smaller than the second diameter, the narrowing of the narrow sections lowered into the opening areas of the pits referring to this reduction of diameter. These narrow sections correspond to the regions (with narrowed cross-section), located in the x-y plane, of the first invention.

The insulating layer (and a part of the insulating layer engaging in the pit, respectively) may, sectionwise, have a first layer thickness and the thickenings of the insulating layer may, sectionwise, have a second layer thickness. A ratio of the first layer thickness to the second layer thickness may be between 100:105 and 100:150. Preferably, it is between 100:110 and 100:115.

Each region having a narrowed cross-section is preferably configured such that it is able to conduct a specific threshold current. Any current above this threshold value can lead to (at least) partial melting of the material of the region having a narrowed cross-section, so that a flow of current will no longer be possible. The pit capacitor is separated from the array of capacitors and, due to its damage, cannot cause such damage to the power semiconductor to be protected.

A further semiconductor device according to the present invention is provided for integration into a power module with at least one deactivatable power semiconductor. It comprises a semiconductor layer, an electrically conductive layer, an insulating layer and a further electrically conductive layer. The semiconductor layer has a first side having a plurality of depressions as pits. The electrically conductive layer is deposited on a second side of the semiconductor layer that is located opposite to the first side. The insulating layer is deposited on the first side of the semiconductor layer and extends into the pits.

The further electrically conductive layer is deposited on the insulating layer and has a plurality of narrow sections. The narrow sections determine the current carrying capacity of a respective pit capacitor. If a plurality of pit capacitors are associated as a group with the subregion of the further electrically conductive layer, the current carrying capacity of this group is determined.

Each of the narrow sections will connect an areally small portion to an areally large portion in an electrically conductive manner, but is also capable of disconnecting it (the small portion) in an electrically separating manner.

Electrical disconnection may take place, for example, when a certain current density is exceeded during operation in one of the narrow sections and when this leads to a power conversion that causes this one narrow section to melt through. An areally small (smaller) portion can thus be disconnected from the areally large portion through this one narrow section.

Each narrow section can transmit a maximum power of 80 mW to 2000 mW, preferably 200 mW to 800 mW.

At least some of the narrow sections may be located in the depressions.

The insulating layer may have thickenings in opening areas of the depressions.

The thickenings in the opening areas of the depressions may correspond to the narrow sections of the further electrically conductive layer.

Below each of the narrow sections, a cavity may be formed in the depression.

Melting of one of the narrow sections may melt material that will enter the cavity located therebelow in the depression in question.

The narrow sections may alternatively be located on the first side of the semiconductor layer, outside or above the depressions.

The respective narrow sections may be arranged above and outside the openings of the depressions.

A narrow section may be associated with a plurality of depressions. In this way, an electrically coupled group of relief capacitors is formed.

A narrow section may also be associated with only one respective depression.

The narrow sections may preferably be configured to be cut or split by a flow of current, in particular a flow of current of such a magnitude that it exceeds a threshold value exceeding the current carrying capacity (as the melting current density of the selected metal). The melting current density is the current density (here in the narrow section) at which the conductor temperature (the temperature of the narrow section) increases to the melting temperature (of the selected metal) after 1/100 s of load (i.e. 10 ms) (value according to Müller-Hildebrand, https://de.wikipedia.org/wiki/Elektrische Stromdichete, version of Jul. 19, 2019, time 17:04), and indicated for direct current, without skin effect.

Each of the areally smaller portions occupies an area that is less than 1/10 to less than 1/100 of the area of the areally larger portion.

A suggested method of operating a power module including a multi-layer semiconductor device, preferably one of the semiconductor devices of the type described hereinbefore, comprises that narrow sections acting as electrical connection conductive paths in an electrically conductive layer of the multi-layer semiconductor device melt at electrical currents higher than a predefined threshold value, and no longer conduct electrically, whereby defective elements acting as capacitors are isolated, in a singulated form, from a plurality of elements of the multi-layer semiconductor device that are connected in parallel and act as capacitors.

The semiconductor device may be one of the following ones:

A semiconductor device, integrated in a power module with at least one deactivatable power semiconductor, the semiconductor device comprising
(a) a semiconductor layer, a first side of the semiconductor layer having a plurality of depressions as pits;
(b) an electrically conductive layer, the electrically conductive layer being deposited on a second side of the semiconductor layer that is located opposite to the first side;
(c) an insulating layer, the insulating layer being deposited on the first side of the semiconductor layer and extending into the pits;
(d) a further electrically conductive layer for contacting the semiconductor device, the further electrically conductive layer being deposited on the insulating layer and the further electrically conductive layer having a plurality of narrow sections.

A semiconductor device integrated in a power module, the semiconductor device comprising
(a) a semiconductor layer, a first side of the semiconductor layer being provided with a plurality of depressions as pits;
(b) an insulating layer, the insulating layer being deposited on the first side of the semiconductor layer and extending into the pits;
(c) a first electrically conductive layer for contacting the semiconductor device, the first electrically conductive layer being deposited on the insulating layer and extending into, but not filling, the pits; and
(d) a second electrically conductive layer, the second electrically conductive layer being deposited on a second side of the semiconductor layer located opposite to the first side;
wherein the insulating layer has thickenings in opening areas of the pits, a respective thickening defining a conductive region having a narrowed cross-section in the first electrically conductive layer.

A semiconductor device integrated in a power module, the semiconductor device comprising
(a) a semiconductor layer, a first side of the semiconductor layer having a plurality of depressions;
(b) an insulating layer, the insulating layer being deposited on the first side of the semiconductor layer and engaging in the depressions;
(c) a first electrically conductive layer for contacting the semiconductor device, the first electrically conductive layer being deposited on the insulating layer; and
(d) a second electrically conductive layer for contacting the semiconductor device, the second electrically conductive layer being deposited on a second side of the semiconductor layer opposite to the first side;
   wherein the first electrically conductive layer has a plurality of recesses and a plurality of subregions, and each subregion is enclosed by at least one recess, leaving at least one region having a narrowed cross-section.

The above-mentioned threshold value may be between 20.0 mA and 500.0 mA. Preferably, it may be between 50.0 mA and 200.0 mA.

A melting of one of the narrow sections will melt material of the narrow section that can enter the cavity located below the narrow section.

### INTRODUCTION TO THE DRAWINGS

The embodiments of the present invention are shown on the basis of examples and are not shown in a manner in which limitations from the figures or more concrete forms are read into the claims as long as these limitations or concretizations have not been incorporated in the latter. Like reference numerals in the figures designate like elements.

FIG. 1A shows, in a top view, a schematic partial view of a semiconductor device 1 having a plurality of annular, non-closed recesses 20 in a contacting layer 14 of the semiconductor device 1;

FIG. 1B shows a first schematic sectional view A-A of the semiconductor device 1;

FIG. 1C shows a second schematic sectional view B-B of the semiconductor device 1 in the region 22 between the two free ends of the recess 20, also referred to as narrow section 22;

FIG. 2 shows, in a top view, schematic representations of possible basic shapes of at least one—preferably of all—recesses 20 in the contacting layer 14 of the semiconductor device 1, which have at least one narrow section 22;

FIG. 3A shows, in a top view, a schematic partial view of a further semiconductor device 2 having a plurality of oval ring-shaped recesses 20 in a contacting layer 14 of the semiconductor device 2;

FIG. 3B shows a schematic sectional view C-C of the semiconductor device 2;

FIG. 4A shows a schematic sectional view of a further semiconductor device 3 in an embodiment without recesses in a first contacting layer 14 of the semiconductor device 3;

FIG. 4B shows a schematic sectional view D-D of the semiconductor device 3 for illustrating the region 32 with the narrowed cross-section; also this region will be referred to as narrow section 22.

### DETAILED DESCRIPTION

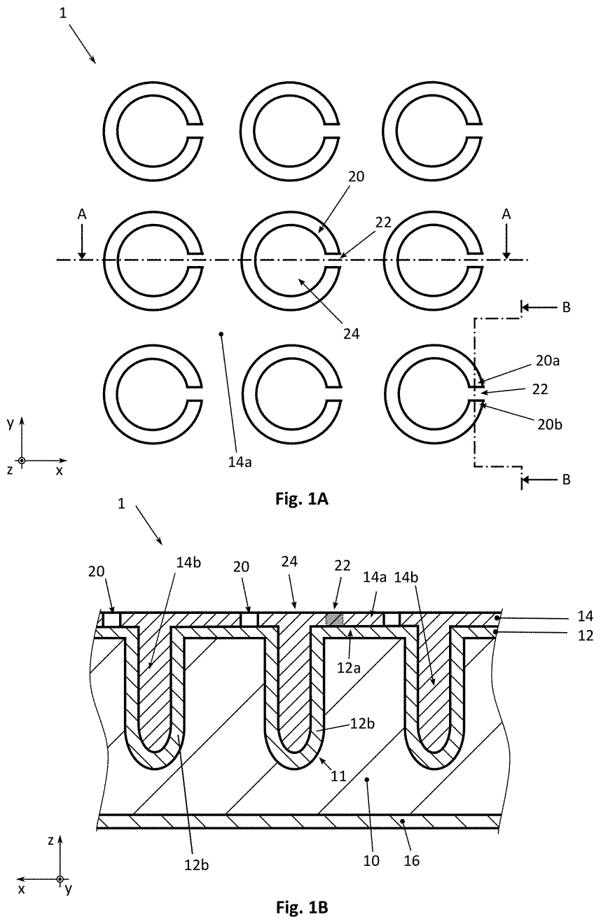

FIG. 1A shows, in a top view, a schematic partial (sectionwise) view of a semiconductor device 1 having a plurality of annular recesses 20 in a contacting layer 14 of the semiconductor device 1. The recesses 20 are not closed. A portion 22 of the contacting layer 14 remains.

For the purpose of orientation, an x-y-z coordinate system is drawn in. The axis z is the height direction. The x-y axes circumscribe the plane in which the pit capacitors are arranged in a distributed manner.

In FIG. 1A, a total of nine recesses 20 are shown in the contacting layer 14 of the semiconductor device 1. However, the semiconductor device may have more than nine recesses 20, preferably several hundred recesses 20, each of them having the portion 22.

Through the recesses 20 in the contacting layer 14 as a first electrically conductive layer of the semiconductor device 1, regions 22 with narrowed cross-sections are defined in the first electrically conductive layer 14. What is shown here are (connection) webs 22. In addition, smaller subregions 24 are exempted in (or from) the first electrically conductive layer 14. In this context, “exempted” means that, parallel to the z-axis, a respective (side) surface is “separated” or delimited by a respective recess in the first electrically conductive layer, and that a subregion 24 will thus remain electrically conductively connected to the rest of the first electrically conductive layer only by the narrow sections 22 (also referred to as “webs”). The respective recesses 20 additionally delimit the subregions 24, with ends 20a and 20b of the respective recess 20 approaching each other closely and thus defining a lateral extension of the narrow section 22 (as a web).

A respective subregion 24 means a planar region of the first electrically conductive layer 14, which is exempted through the recess 20 and is connected to the planar region 14a of the first electrically conductive layer 14 only via the narrowed conductive cross-section. The conductive connection is intended to become non-conductive, when the exemption defined as a narrow section 22 becomes an exposure, i.e. is physically separated, as will be explained in more detail hereinafter.

The first electrically conductive layer 14 is to be understood functionally, with the planar region 14a and the regions 14b having a finger-shaped form, as will be explained hereinafter.

A view of section A-A is shown in FIG. 1B, and a view of section B-B is shown in FIG. 1C.

In FIG. 1B, it can be seen that the semiconductor device 1 is composed of a plurality of layers. A layer 16 constituting the lowermost layer when seen in the z-direction and representing a second electrically conductive layer of the semiconductor device 1 is used for electrically contacting the semiconductor device 1.

A semiconductor layer 10 is arranged on and above the second electrically conductive layer 16, respectively. The semiconductor layer 10 has a plurality of depressions 11, the number of depressions shown here being three. However, the semiconductor layer 10 may have significantly more than three depressions 11, preferably the semiconductor layer may have several hundred depressions 11.

An insulating layer 12 is deposited on the semiconductor layer 10. Corresponding to the surface of the semiconductor layer 10, the insulating layer 12 has a region 12a, which is flat and parallel to the x,y plane, and regions 12b whose outer contours correspond to the shape of the depressions 11 and engage in the depressions 11.

The number of depressions 11 may correspond to the number of recesses 20. The number of depressions 11 may be higher than the number of recesses 20. In a sectional view, the depressions 11 in FIG. 1B are U-shaped (2D, x,z-plane).

The depressions 11 may have a finger-shaped form (3D view). Finger-shaped means that each depression 11, which is recessed into the semiconductor layer 10 as a pit, may have a cylindrical portion and a hemispherical portion. Accordingly, an upper edge contour of an opening of a depression 11, as viewed in the z-direction, is defined by the cylindrical portion (circular edge contour).

The depressions 11 may also have other geometries. For example, the depressions 11 may be configured as trenches.

The depressions 11 may be arranged uniformly, i.e. at uniform distances (x,y plane) from one another, in the semiconductor layer 10.

The semiconductor layer 10 has a largest layer thickness in the semiconductor device. The depressions 11 may extend into the semiconductor layer 10 up to and beyond half of the layer thickness of the semiconductor layer 10.

The semiconductor layer is parallel to an x,y plane (it is planar).

The semiconductor layer 10 has deposited thereon an insulating layer 12. Corresponding to a surface contour of the semiconductor layer 10, the insulating layer 12 comprises a planar region 12a (parallel to the x,y plane) and regions 12b having a finger-shaped configuration, which engage in the depressions 11 and cover the side walls of the latter.

The insulating layer 12 may have a uniform layer thickness.

The insulating layer 12 has the first electrically conductive layer 14 deposited thereon. In FIG. 1B it can be seen that, corresponding to a surface contour of the insulating layer 12, the first electrically conductive layer 14 is divided into a planar region 14a (parallel to the x,y plane) and regions 14b having a finger-shaped form, which engage in the depressions 11 and fill them (as a filling material).

The partially dashed outlined and grayed area here indicates a position of a region 22 having a narrowed cross-section, viewed in the x,y plane.

A subregion 24 means a planar region of the first electrically conductive layer 14, which is exempted through the recess 20 and is connected to the planar region 14a of the first electrically conductive layer 14 only via a respective portion 22 having a narrowed cross-section, without taking into account the filling material 14b in a depression 11 that corresponds to the recess 20.

In this example, each recess 20 and each subregion 24, respectively, is associated with a respective depression 11. Each subregion 24 in the first electrically conductive layer 14 extends radially in the x,y plane up to and beyond an opening of a coated depression 11.

The recesses 20 are arranged in the first electrically conductive layer such that they each define, sectionwise, a planar region 12a and a finger-shaped recessed region 12b of the insulating layer 12.

Hence, the insulating layer 12 is to be understood functionally.

In FIG. 1C it can be seen that a region 22 having a narrowed cross-section, representative for all regions 22 having a respective narrowed cross-section in the first electrically conductive layer, has a width b_{A} and a height h_{A}, i.e. it has a cross-section h_{A}·b_{A}.

The width b_{A} and the height h_{A} are configured such that the narrowed cross-section—compared to the recess 20—can conduct a current of a defined current level. Up to this current, the region 22 having a narrowed cross-section can conduct the electric current without damage being caused. A current above the defined current level is intended to cause melting or sublimation of the region 22 having a narrowed cross-section, so that current can no longer be conducted across this region.

Also a length of the region 22 having a narrowed cross-section may have an influence on the timing of the interruption of current conduction and may be adjusted accordingly.

The height h_{A} of the region 22 having a narrowed cross-section may substantially be determined by a layer thickness of the planar region 14a of the first electrically conductive layer 14, and may preferably correspond to the layer thickness of the planar region 14a.

By melting or sublimating the region 22 having a narrowed cross-section, a region of the semiconductor device 1 forming an element that acts as a (pit) capacitor within the semiconductor device 1 can thus be electrically isolated from the rest of the semiconductor device 1 to the greatest possible extent. The exemption of the small subregion leads to a separation or exposure of the pit capacitor in question. It can here be said that the current destroying the narrow section could be the cause of a fault, in particular a short circuit of the one relief network (consisting of the RC element). The other pit capacitors connected in parallel continue to operate without any damage being caused.

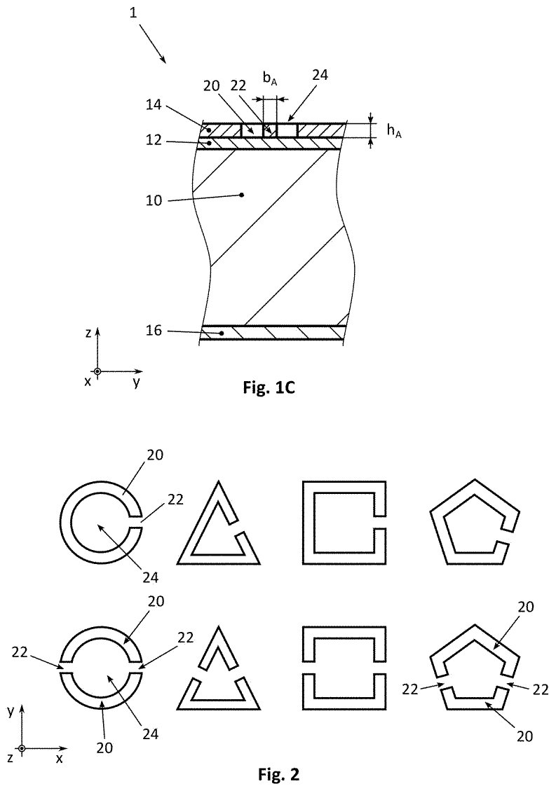

FIG. 2 shows, in a top view, schematic representations of possible basic shapes of recesses 20 in a contacting layer 14 of a semiconductor device. One basic shape is here intended to be representative for all recesses 20 in the first electrically conductive layer 14 of a semiconductor device, e.g. semiconductor device 1.

The annular recess 20 (first row, first shape) corresponds to the shape as already shown and explained in FIG. 1A.

The recesses 20 may also have other basic shapes. The basic shape of the recesses 20 may be triangular (first row, second shape), square or rectangular (first row, third shape) or pentagonal or polygonal (first row, fourth shape). The depressions 11 may also be non-circular in shape, e.g. as trenches.

So far, an example has been considered in which one recess 20 is associated with one depression 11. However, a depression 11 may also have associated therewith a plurality of recesses 20, or a plurality of depressions may define an exempted subregion 24.

This is shown exemplarily in the second row of FIG. 2. The first shape in the second row of FIG. 2 still has a circular basic shape, but is formed by two semi-annular recesses 20 defining two regions 22 with a narrowed cross-section in the first electrically conductive layer. The current carrying capacity is doubled.

The same applies to the other design forms of the recesses 20. The various basic shapes (triangle, rectangle, polygon, etc.) remain essentially unchanged, but are formed by two or more than two recesses 20. The number of recesses 20, by means of which a subregion 24 is formed or exempted, correspondingly also determines the number of regions 22 having a narrowed cross-section, i.e. the number of narrow sections.

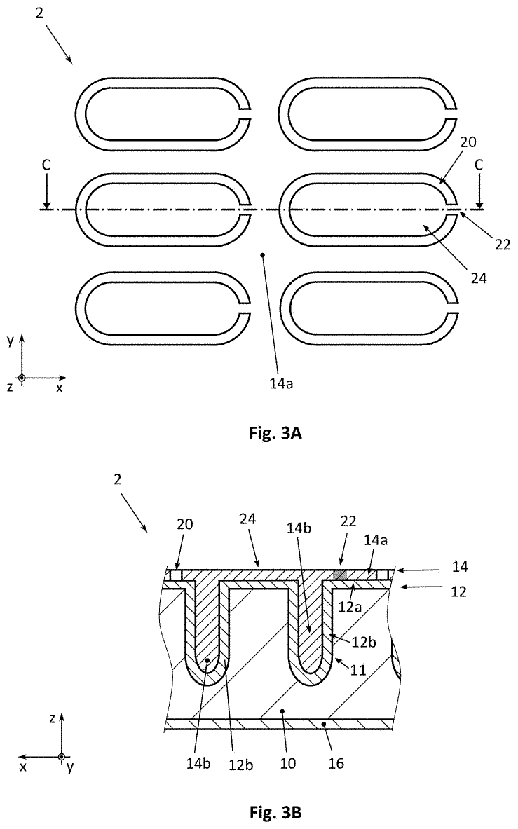

FIG. 3A shows, in a top view, a schematic partial view of a semiconductor device 2 having six oval ring-shaped recesses 20 in a contacting layer 14 of the semiconductor device 2. The contacting layer 14 is a first electrically conductive layer of the semiconductor device 2.

The recesses 20 in the first electrically conductive layer 14 of the semiconductor device 2 each enclose a subregion 24 in the first electrically conductive layer 14, leaving a region 22 having a narrowed cross section. Through the recesses 20, the subregions 24 are exempted on one side thereof.

A sectional view of the semiconductor device 2 (section C-C) is shown in FIG. 3B.

From the sectional view of FIG. 3B it can be seen that the semiconductor device 2 has a layer structure corresponding to that of the semiconductor device 1 according to FIG. 1A, 1B and 1C, with the difference that a respective recess 20 encloses two depressions 11, and one recess 20 is associated with two depressions 11, respectively.

A respective recess 20 may also be associated with more than two depressions 11. The function is the same as that in the case of FIG. 1. Disconnecting one pit capacitor then corresponds to electrically disconnecting a group of pit capacitors, in the example in question two.

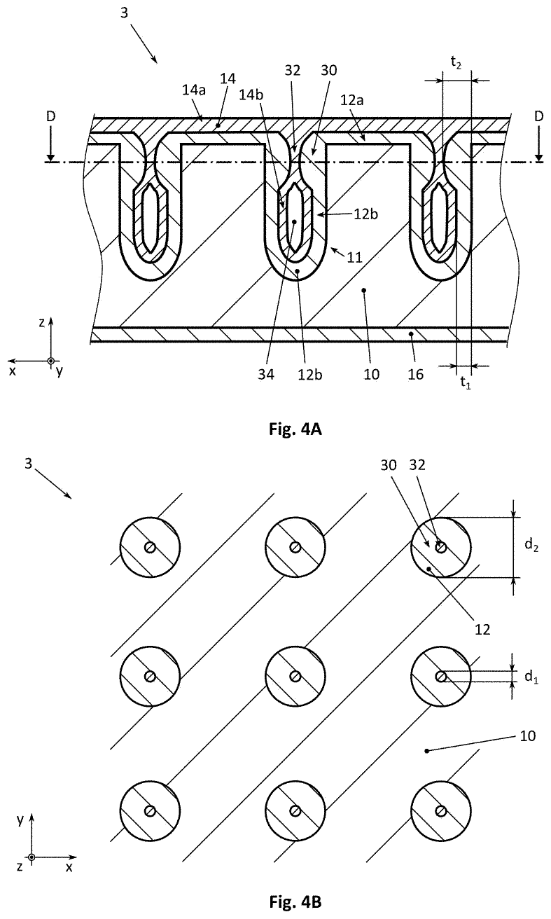

FIG. 4A shows a schematic sectional view of a semiconductor device 3 in an alternative embodiment without recesses in a first contacting layer 14 of the semiconductor device 3.

The semiconductor device 3 has a layered structure or layered design. The lowermost layer 16, when seen in the z-direction, is a second electrically conductive layer for contacting the semiconductor component 3. The second electrically conductive layer 16 has deposited thereon a semiconductor layer 10.

The semiconductor layer 10 has deposited thereon an insulating layer 12. Corresponding to the surface of the semiconductor layer 10, the insulating layer 12 has a region 12a that is flat and parallel to the x,y plane, and regions 12b whose outer contours correspond to the shape of the depressions 11 and engage in the depressions 11, respectively.

The semiconductor layer 10 has a plurality of depressions 11, the total number of depressions 11 shown here being three.

The semiconductor device 3 may have more than three depressions 11, preferably the semiconductor device 3 may have several hundred depressions 11.

The depressions 11 may be arranged at uniform distances (x,y plane) from one another in the semiconductor layer 10.

The depressions 11 may extend on one side down to more than half of a layer thickness of the semiconductor layer 10, i.e. extend into the semiconductor layer 10 (in a negative z-direction).

The depressions 11 preferably have a finger-shaped form. This means that each depression 11 has, sectionwise, a cylindrical portion and a portion that is hemispherical in shape. Accordingly, an opening of the depression 11 has a circular edge contour.

The depressions may have a different shape, e.g. the shape of a parallelepiped or that of a trench. The depressions 11 enlarge a surface area of the semiconductor layer 10.

The semiconductor layer 10 has deposited thereon an insulating layer 12. Corresponding to the surface of the semiconductor layer 10, the insulating layer 12 has a region 12a that is flat and parallel to the x,y plane, and regions 12b whose outer contours correspond to the shape of the depressions 11 and engage in the depressions 11, respectively. In addition, the insulating layer 12 has, in each opening area of each depression 11, a thickening 30 that extends radially inwards (in the direction of an axis of the depression 11) from the respective cylindrical portion of the depression 11.

With the exception of the thickenings 30, the insulating layer 12 has a uniform layer thickness t₁. The thickenings have a maximum layer thickness t₂. The layer thickness t₁ is smaller than the layer thickness t₂ of the thickenings.

Corresponding to a surface geometry of the insulating layer 12, the first contacting layer 14, which represents the first electrically conductive layer, has regions 14b that engage in the coated depressions 11, and a region 14a that is parallel to the x,y plane.

Due to the thickenings 30 in the insulating layer 12, the first electrically conductive layer 14, and the regions 14b that engage in the coated depressions 11, respectively, each have a region 32 having a narrowed cross-section for each depression 11.

The first electrically conductive layer 14 may, for example, be grown or deposited on the insulating layer 12 (thermal oxidation, oxides or nitrides deposited from the gas phase, gas phase deposition, sputtering, etc.).

As a result of the process, electrically conductive material of the first electrically conductive layer 14 may pass through and deposit in the region 32 having a narrowed cross-section, but only until the region 32 having a narrowed cross-section will be closed by deposited material, so that a cavity 34, which is not filled with electrically conductive material (gas inclusion), will be formed below the region 32 having a narrowed cross-section. Accordingly, the depressions 11 coated with the insulating layer 12 may be filled only partially with material of the electrically conductive layer 14.

Each region 32 having a narrowed cross-section may in particular be configured such that it can conduct exclusively a current of a prespecified strength or magnitude without damage being caused. If a current above this current threshold flows through one of the regions 32 having a narrowed cross-section, this will have the effect that the region 32 having a narrowed cross-section melts. As a result, current can no longer be conducted through the region 32 having a narrowed cross-section.

Molten material of the region 32 can deposit in the cavity 34, which is not filled with material of the first semiconductor layer 14. As a result, current can no longer be conducted through the region 32 having a narrowed cross-section.

A (partial) sectional view of the semiconductor device 3 (section D-D) is shown in FIG. 4B.

In FIG. 4B, a total of nine depressions 11 are shown in a sectional view. As has already been mentioned above, the semiconductor device 3 may have a significantly higher number of depressions 11 (not shown).

Each finger-shaped depression 11 has, at least sectionwise, an insulating diameter d₂ (in the sectionwise cylindrical portion of the depression). The region 32 having a narrowed cross-section has a conductive diameter d₁ therein.

The diameter d₂ of the depression is larger than the diameter d₁ of the region 32 having a narrowed cross-section. The ratio of the two diameters to each other may, in particular, be configured such that the region 32 having a narrowed cross-section (the narrow section) of the first electrically conductive layer 14 can conduct a current of a specific strength without damage being caused. In other words, above this current threshold the narrow section 32 will melt.

In the event that this limit current is exceeded in one of the regions 32 having a narrowed cross-section, material in the diameter d₁ will be melted, as has already been mentioned above, so that a region of the semiconductor device will electrically be isolated from the rest of the semiconductor device.

1. A semiconductor device for integration into a power module, the semiconductor device comprising
(a) a semiconductor layer (10), a first side of the semiconductor layer (10) having a plurality of depressions (11);
(b) an insulating layer (12; 12a, 12b), the insulating layer being deposited on the first side of the semiconductor layer (10) and engaging in the depressions (11);
(c) a first electrically conductive layer (14; 14a, 14b) for contacting the semiconductor device (1, 2), the first electrically conductive layer (14; 14a, 14b) being deposited on the insulating layer (12a, 12b); and
(d) a second electrically conductive layer (16) for contacting the semiconductor device (1, 2), the second electrically conductive layer (16) being deposited on a second side of the semiconductor layer (10) opposite to the first side;
wherein the first electrically conductive layer (14; 14a, 14b) has a plurality of recesses (20, 20) and a plurality of subregions (24), and each subregion (24) is enclosed by at least one recess (20), leaving at least one region (22, 22) having a narrowed cross-section.

2. The semiconductor device according to claim 1, wherein at least some of the subregions (24) of the first electrically conductive layer (14; 14a, 14b) are enclosed by a plurality of recesses (20, 20), leaving a plurality of regions (22, 22) having a narrowed cross-section.

3. The semiconductor device according to claim 1, wherein the regions (22) having a narrowed cross-section in the first electrically conductive layer (14; 14a, 14b) each have a height (h_{A}) between 100.0 nm and 1.0 μm and a width (b_{A}) between 50.0 nm and 5.0 μm.

4. The semiconductor device according to claim 1, wherein the respective regions (22) having a narrowed cross-section are identical in height (h_{A}) and identical in width (b_{A}).

5. The semiconductor device according to claim 1, wherein the respective one subregion (24) of the first electrically conductive layer (14; 14a, 14b) at least partially covers, or completely covers, an opening of a depression (11), or extends radially beyond an edge of the respective opening of the depression (11).

6. The semiconductor device according to claim 1, wherein the respective one subregion (24) of the first electrically conductive layer (14; 14a, 14b) at least partially covers, or completely covers, a plurality of openings of associated depressions (11), or extends radially beyond edges of the respective openings.

7. The semiconductor device according to claim 1, wherein the recesses (20) have a partially circular, circular, rectangular or polygonal basic shape.

8. A semiconductor device for integration into a power module, the semiconductor device comprising
(a) a semiconductor layer (10), a first side of the semiconductor layer (10) being provided with a plurality of depressions (11) as pits;
(b) an insulating layer (12; 12a, 12b), the insulating layer being deposited on the first side of the semiconductor layer (10) and extending into the pits (11);
(c) a first electrically conductive layer (14; 14a, 14b) for contacting the semiconductor device (3), the first electrically conductive layer (14; 14a, 14b) being deposited on the insulating layer (12; 12a, 12b) and extending into, but not filling (34), the pits (11); and
(d) a second electrically conductive layer (16), the second electrically conductive layer (16) being deposited on a second side of the semiconductor layer (10) located opposite to the first side;
wherein the insulating layer (12) has thickenings (30) in opening areas of the pits (11), a respective thickening (30) defining a conductive region (32) having a narrowed cross-section in the first electrically conductive layer (14; 14a, 14b).

9. The semiconductor device according to claim 8, wherein the regions (32) having a narrowed cross-section in the first electrically conductive layer (14) each have a first diameter (d₁) between 100.0 nm and 2.0 μm.

10. The semiconductor device according to claim 8, wherein each pit (11) has, at least sectionwise, a second diameter (d₂) in the opening area of the respective pit (11), wherein a ratio (d₁:d₂) of a first diameter (d₁) to the second diameter (d₂) of the conductive region (32) having the narrowed cross-section is between 1:2 and 1:20.

11. The semiconductor device according to claim 8, wherein the insulating layer (12; 12a, 12b) has, sectionwise, a first a layer thickness (t₁), and the thickenings (30) of the insulating layer have a second layer thickness (t₂), wherein a ratio (t₁:t₂) of the first layer thickness (t₁) to the second layer thickness (t₂) is between 100:105 and 100:150.

12. A semiconductor device for integration into a power module with at least one deactivatable power semiconductor, the semiconductor device comprising
(a) a semiconductor layer (10), a first side of the semiconductor layer (10) having a plurality of depressions (11) as pits;
(b) an electrically conductive layer (16), the electrically conductive layer (16) being deposited on a second side of the semiconductor layer (10) that is located opposite to the first side;
(c) an insulating layer (12; 12a, 12b), the insulating layer being deposited on the first side of the semiconductor layer (10) and extending into the pits (11);
(d) a further electrically conductive layer (14; 14a, 14b) for contacting the semiconductor device (3), the further electrically conductive layer (14; 14a, 14b) being deposited on the insulating layer (12) and the further electrically conductive layer (14; 14a, 14b) having a plurality of narrow sections (22, 32).

13. The semiconductor device according to claim 12, wherein each of the narrow sections (22, 32) connects an areally small portion (24) to an areally large or larger portion in an electrically conductive manner, but is also capable of disconnecting the small portion in an electrically separating manner.

14. The semiconductor device according to claim 12, wherein at least some of the narrow sections (32) are located in the depressions (11).

15. The semiconductor device according to claim 14, wherein the insulating layer (12) has thickenings (30) in opening areas of the depressions (11).

16. The semiconductor device according to claim 15, wherein the thickenings (30) in opening areas of the depressions (11) correspond to the narrow sections (32) of the further electrically conductive layer (14; 14a, 14b).

17. The semiconductor device according to claim 12, wherein the narrow sections (22) are located on the first side of the semiconductor layer (10), outside or above the depressions (11).

18. The semiconductor device according to claim 12, wherein one narrow section (22) is associated with a plurality of depressions (11).

19. The semiconductor device according to claim 12, wherein a plurality of narrow sections (22) are associated with a depression (11).

20. The semiconductor device according to claim 12, wherein the narrow sections (22, 32) are configured to be cut or split by a flow of current.

21. The semiconductor device according to claim 13, wherein each of the areally smaller portions (24) occupies a conductive area that is less than 1/10 or less than 1/100 of the area of the areally larger portion (14b).

22. The semiconductor device according to claim 14, wherein below each of the narrow sections (32) a cavity (34) is formed in the depression (11).

23. The semiconductor device according to claims 14 and 20, wherein melting of one of the narrow sections (32) will melt material that enters the cavity (34) located therebelow in the depression (11) in question.

24. A method of operating a power module including a multi-layer semiconductor device,
(a) wherein narrow sections (22, 32) acting as electrical connection conductive paths in an electrically conductive layer (14; 14a, 14b) of the multi-layer semiconductor device melt at electrical currents higher than a predefined threshold value, and no longer conduct electrically,
(b) whereby defective elements acting as capacitors are isolated, in a singulated form, from a plurality of elements of the multi-layer semiconductor device that are connected in parallel and act as capacitors.

25. The method according to claim 24, wherein the threshold value is between 20.0 mA and 500.0 mA.

26. The method according to claim 24, wherein melting of one of the narrow sections (32) will melt material that enters a cavity (34) located below the narrow section (32).
